(19) United States
(12) Patent Application Publication
(10) Pub. No.: US 2013/0187024 A1
(43) Pub. Date: Jul. 25, 2013

(54) PORTABLE SUPPORT DEVICE

(71) Applicants: Douglas M. Obujen, Sunnyvale, CA (US); Jeff R. Burdick, Mountain View, CA (US)

(72) Inventors: Douglas M. Obujen, Sunnyvale, CA (US); Jeff R. Burdick, Mountain View, CA (US)

(21) Appl. No.: 13/356,864

(22) Filed: Jan. 24, 2012

(51) Int. Cl. H05K 7/00

(52) U.S. Cl. 248/693

(57) ABSTRACT

A portable support device is configured to receive a portable electronic device thereon, and includes a generally planar support base, a neck strap, and two struts coupled at one end to the support base and at the other end to the neck strap. The struts can rotate with respect to the support base. The neck strap can be worn around a user's neck, allowing the support base to rest in front of a user's mid-section. Spacer bars can provide for separation between the user's mid-section and the support base. Clamps or other fixing mechanisms can be used to retain the portable electronic device on the top surface of the support base. Clasps or clutch plates can be used to restrain the rotational movement of the struts relative to the support base.

### BACKGROUND OF THE INVENTION

1. Field of the Invention

The invention relates to portable support devices. More particularly, this invention relates to wearable support devices for portable electronics.

2. Description of the Related Art

The use of tablet computers, laptops, e-readers, smartphones, and other portable electronic devices has increased dramatically in recent years. While increased mobility is a benefit to users, there is often a need to access such devices in places where a desk or other support surface is unavailable. The user is therefore typically restricted to using the device with one hand, while using the other to hold it in place. This can be particularly burdensome for larger devices, such as laptops or tablet computers, or for environments in which free hands are desirable. There is therefore a need to provide a convenient and easy-to-use portable support device that permits a user to interact with a portable electronic device as though it were on a desktop.

### SUMMARY OF THE INVENTION

In one embodiment, a portable support device is configured to receive a portable electronic device having a bottom surface. The support device can include a generally planar base configured to support the bottom surface of the electronic device, A portable support device configured to receive a portable electronic device having a bottom surface, a substantially flexible neck strap, and a pair of substantially rigid struts, each having a first end coupled to the support base and a second end coupled to the neck strap. The support base can comprise top and bottom opposed surfaces, opposed leading and trailing edges, opposed side edges, and a movement-inhibiting mechanism for retaining the portable electronic device. the support device comprising:

In another embodiment, a portable support device is configured to receive a portable electronic device having a bottom surface. The support device can include a support base configured to receive the portable electronic device, a neck strap configured to rest against a back side of a user's neck, and a pair of substantially rigid struts coupled at one end to the support base and at the other end to the neck strap. The struts can be configured to pass in front of a user's shoulders, such that the support base rests in front of a user's mid-section.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

The invention and various embodiments and features may be better understood by reference to the following drawings in which:

FIG. 1 shows a user wearing a portable support device, according to one embodiment.

FIGS. 2 shows a rear perspective top view of the portable support device of FIG. 1.

FIG. 3 shows a front perspective top view of the portable support device of FIG. 1.

FIG. 4 shows a front elevation view of the portable electronic support device of FIG. 1.

FIG. 5 shows a rear elevation view of the portable support device of FIG. 1.

FIG. 6 shows a side elevation view of the portable support device of FIG. 1.

FIG. 7 shows a bottom plan view of the portable support device of FIG. 1.

FIG. 8 shows a rear elevation view of a portable support device with adjustable clamps, according to one embodiment.

FIGS. 9-10 show detailed views of the adjustable clamps shown in FIG. 8.

FIG. 11 shows a perspective view of a portable support device with a locking clasps, according to one embodiment.

FIGS. 12-13 show detailed views of the locking clasps shown in FIG. 11.

FIG. 14 shows a perspective view of a portable support device with clutch plates, according to one embodiment.

FIGS. 15-16 show detailed views of the clutch plates shown in FIG. 14.

### DETAILED DESCRIPTION OF THE PREFERRED EMBODIMENT

The following detail description of certain embodiments presents various descriptions of specific embodiments of the invention. However, the invention can be embodied in myriad different ways as defined and covered by the claims. In this description, reference is made to the drawings where like reference numerals indicate identical or functionally similar elements. The drawings are schematic and not necessarily drawn to scale.

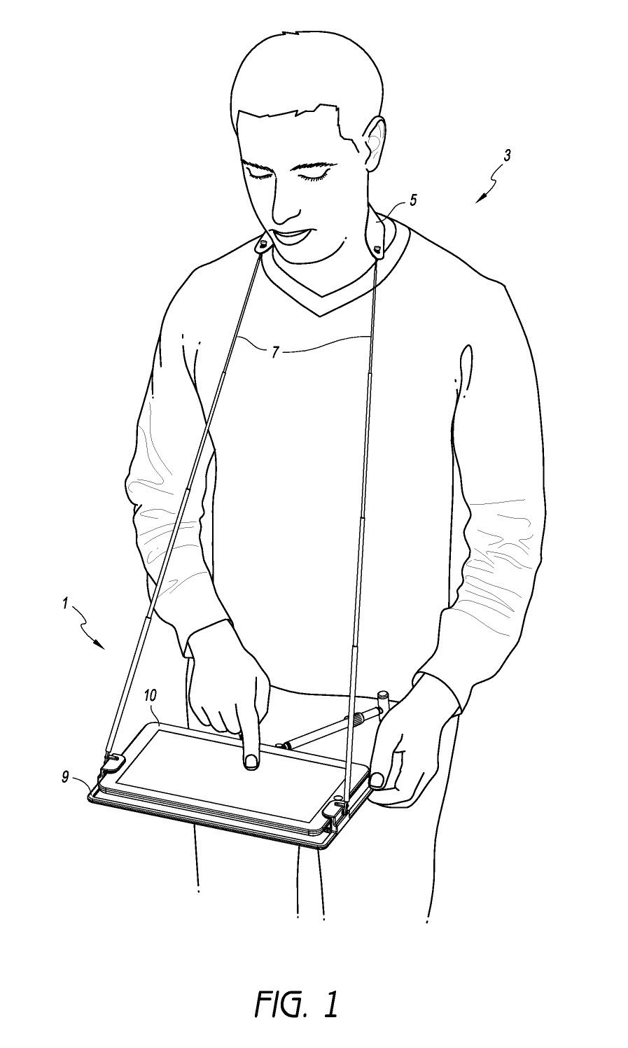

FIG. 1 shows a user wearing a portable support device 1, according to one embodiment. The support device 1 rests in front of a user 3 and includes a flexible neck strap 5, a pair of struts 7, and a support base 9. In some embodiments, the struts 7 can be substantially rigid. In some embodiments, the struts 7 can have adjustable lengths. As illustrated, the neck strap 5 rests against the back of the user's neck. In some embodiments, the neck strap 5 can be flexible. For example, in various embodiments the neck strap 5 can be made from an elastic material, flexible plastic, or cloth. The struts 7 are coupled to the neck strap 5 on one end, and to the support base 9 on the other. A tablet computer 10 is illustrated in position on the support base 9, with its bottom surface facing the top surface of the support base. In use, the tablet computer 10 can be replaced with any number of devices or objects. For example, the support device 1 can receive a laptop computer, e-reader, smartphone, personal digital assistant (PDA), portable DVD player, or similar electronic device, typically including an electronic display screen. Although particularly configured to accommodate such electronic devices, the skilled artisan will appreciate that the device 1 can also be used to support various non-electronic objects. For example, a book, magazine, or clipboard could similarly rest on the support base 9.

In some embodiments, the device 1 is configured such that the support base 9 rests directly or indirectly against the mid-section of user 3. For example, the support base 9 can, in various embodiments, rest against a user's chest, abdomen, waist, or thighs. In one embodiment, the length of the struts 7 can be adjustable. The support base 9 is oriented such that the user 3 can view the tablet computer 11 with ease. As the device 1 supports the weight of the tablet computer 11, the user 3 is free to use his hands for interacting with the tablet computer 11, or for another task.

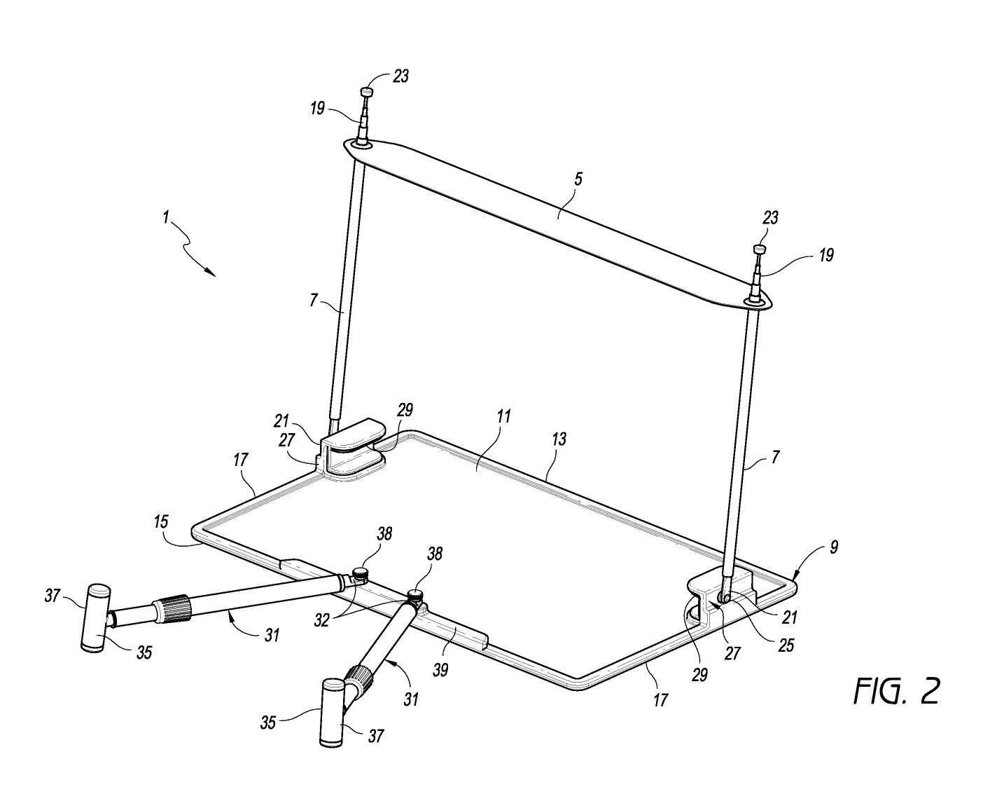

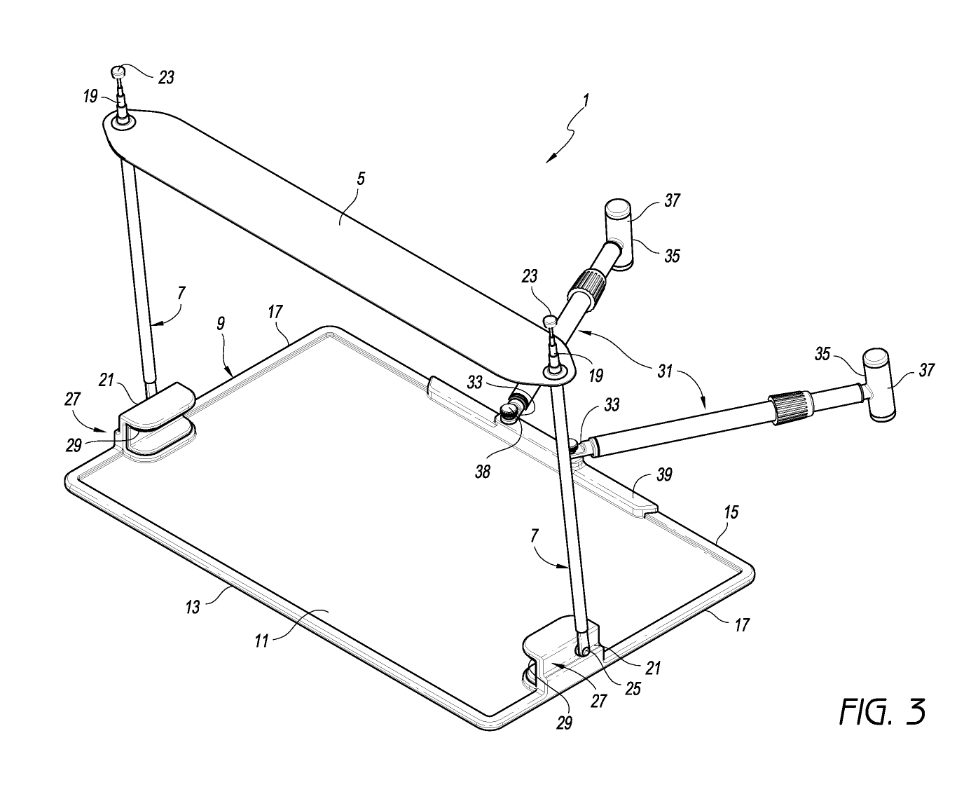

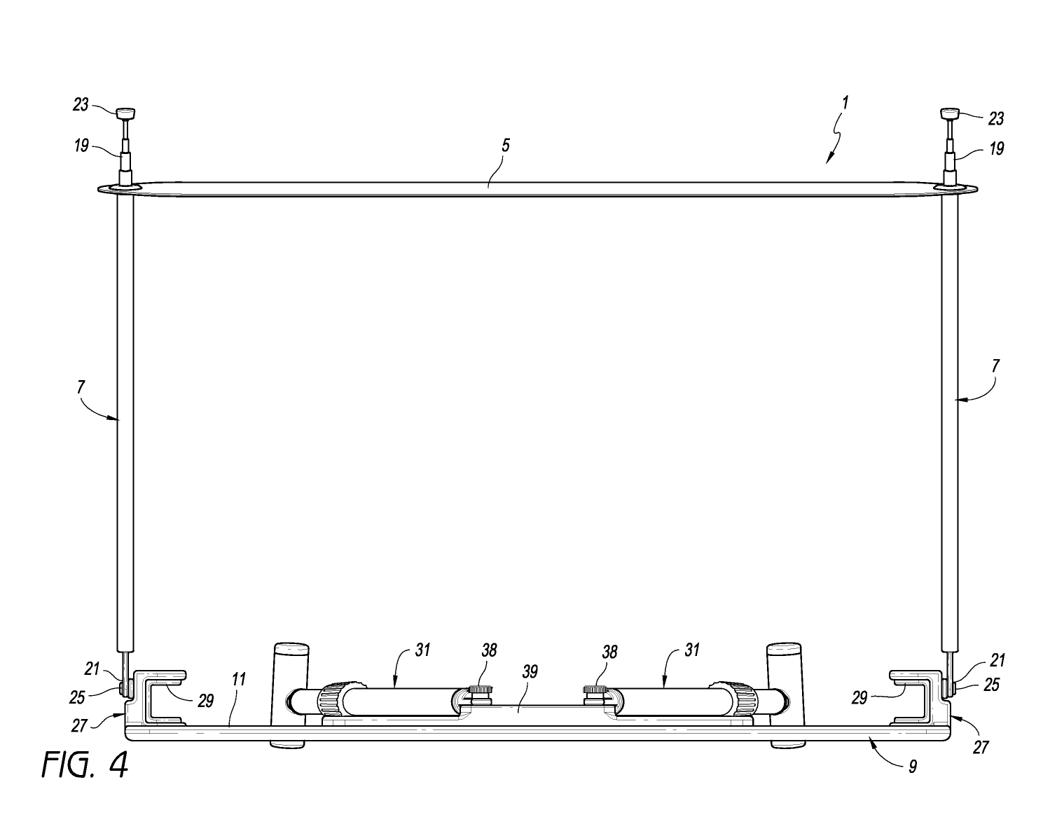

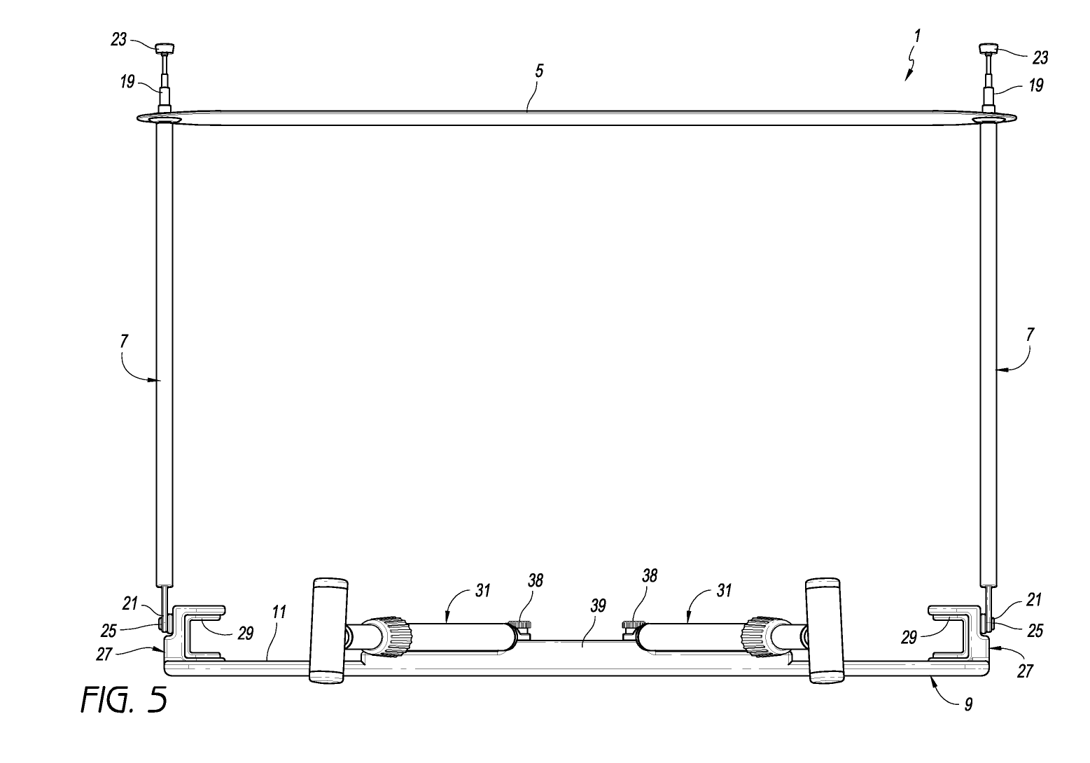

FIGS. 2-5 show several views of the portable support device, according to one embodiment. The support base 9 can include be a generally planar element. As illustrated, the support base 9 includes a top surface 11 configured to receive a portable electronic device. A distal or leading edge 13 is configured to be farther from the user (not shown) than a proximal or trailing edge 15, and opposing side edges 17 connect the leading edge 13 and the trailing edge 15. The support base 9 can be made from a variety of relatively rigid materials. For example, in various embodiments the support base 9 can be made from plastic, metal, hardened glass, or wood.

The struts 7 are shown in a collapsed configuration. As noted above, in some embodiments the struts 7 can have adjustable lengths. As illustrated, each strut 7 is equipped with a telescoping mechanism 19 which allows for adjustable lengths. In some embodiments, the struts 7 can be adjusted to various pre-selected lengths. In other embodiments, the struts 7 can be adjusted continuously to any length within a predetermined range. In some embodiments, the struts 7 are substantially rigid. Each strut 7 is connected to the support base 9 at a first end 21, and connected to the neck strap 5 at a second end 23. In the illustrated embodiment, the strap 5 slidably receives the struts 7 in metal rings sized so that they cannot slide past knobs at the second ends 23 of the struts 7. Attachment of the first end 21 to the support base 9 may employ a hinge joint 25, which allows for each strut 7 to rotate freely in a plane roughly perpendicular to the plane of the support base 9. In some embodiments, the struts 7 can be collapsed and rotated to a position substantially parallel to the plane of the support base 9. Placing the struts 7 in this orientation can allow for the device 1 to be easily transported. For example the device 1 can be placed into a backpack or computer carrier.

Mounted on the top surface 11 near each of the opposing side edges 17 of the support base 9 are two clamps 27. Each clamp 27 includes a clamping surface 29 that is spaced apart from the top surface 11 of the support base 9. In some embodiments, the clamping surface 29 is substantially parallel to the top surface 11. The clamping surface can be coated with a high-friction material to aid in retaining electronic devices or other objects within the clamps. For example the clamping surface can be coated with rubber. In some embodiments, the part or all of the top surface 11 of the support base 9 can be coated with a high-friction material such as rubber. In some embodiments, the clamps 27 are formed integrally with the support base 9. In other embodiments, the clamps 27 are formed separately and later attached to the top surface 11 of the support base 9. The clamps 27 are illustrated as one example of a movement inhibiting mechanism for retaining a portable electronic device against the top surface 11 of the support base 9. In other embodiments, alternative structures or configurations can be used in place of the clamps 27. For example, instead of clamps, a raised edge can be provided along each of the opposing sides, which would serve to retain the portable electronic device onto the top surface of the support base.

A pair of spacing bars 31 are attached to the support base 9 and extend from the trailing edge 15. Each of the spacing bars 31 are attached to the support base 9 at a first end 33 and include a second end 35 that is configured to rest against a user's mid-section. As illustrated, the second ends 35 of the spacing bars 31 can include a knob 37. The knob 37 can be used, for example, simply to rest against the user's body and distribute weight, or can be used to secure the spacing bars 31 to an article of clothing, as a way to secure the position of the support base 9. In one implementation, a portion of each knob 37 can be tucked into a user's belt or waistline. The first end 33 of the spacer bars 35 can be attached to the support base 9 by a hinge joint 38, similar to that used to connect struts 7 to the opposing edges 17 of the support base 9.

A raised lip 39 is shown as an elevated elongated element positioned near the trailing edge 15 of the support base 9. The lip 39 is elongated in a direction substantially parallel to the trailing edge 15. As illustrated, the spacer bars 31 are coupled to the support base 9 by hinge joints 38 which are attached to the lip 39. In other embodiments, the spacer bars 31 can be attached to the support base 9 at a position spaced apart from the lip 39. In use, the lip 39 can serve to support a portable electronic device 10 (FIG. 1) when placed onto the top surface 11 of the support base 9. Often, the support base 9 may be tilted toward the user, such that the leading edge 13 is higher than the trailing edge 15. Accordingly, objects placed onto the top surface 11 of the support base 9 may slide towards the trailing edge 15. The raised lip 39 secures any objects in this configuration, and keeps them from falling off the surface 11 during tilted use. In some embodiments, a raised lip can be formed around other portions of the perimeter of the support base 9. In some embodiments, a raised lip can be formed around the entire perimeter of the support base 9.

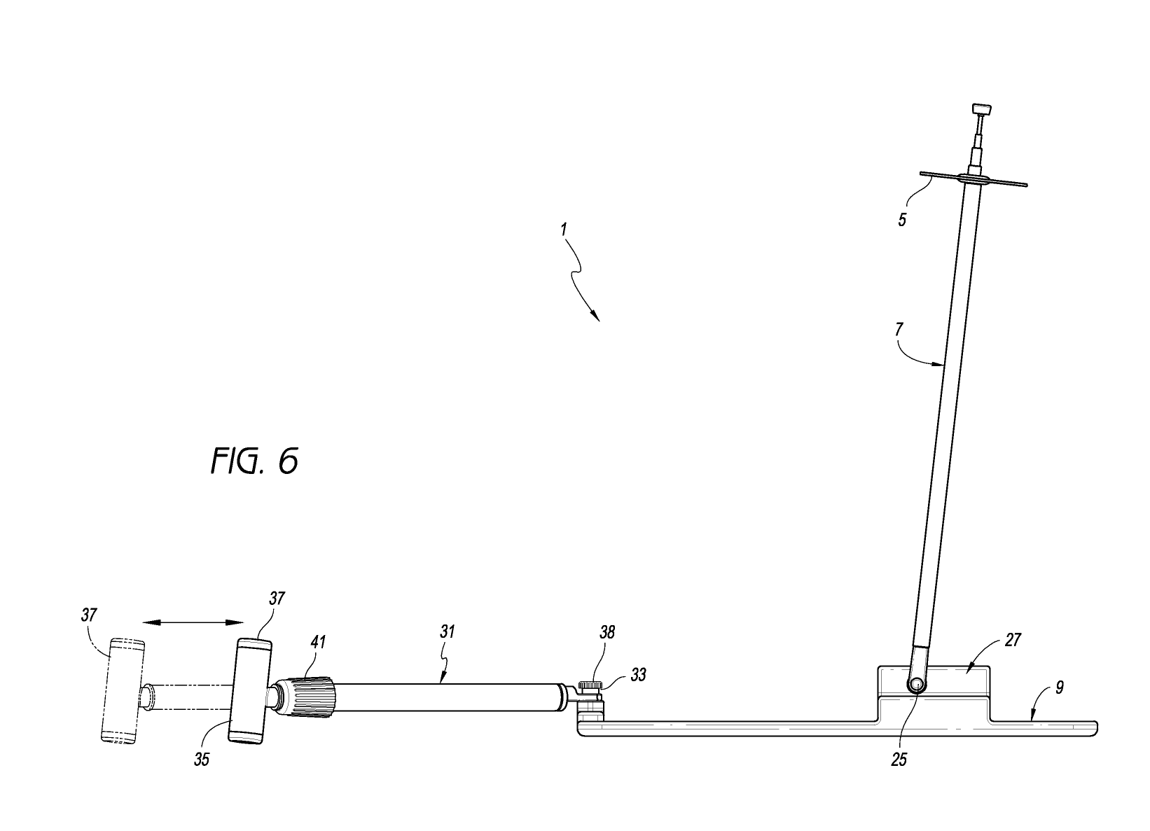

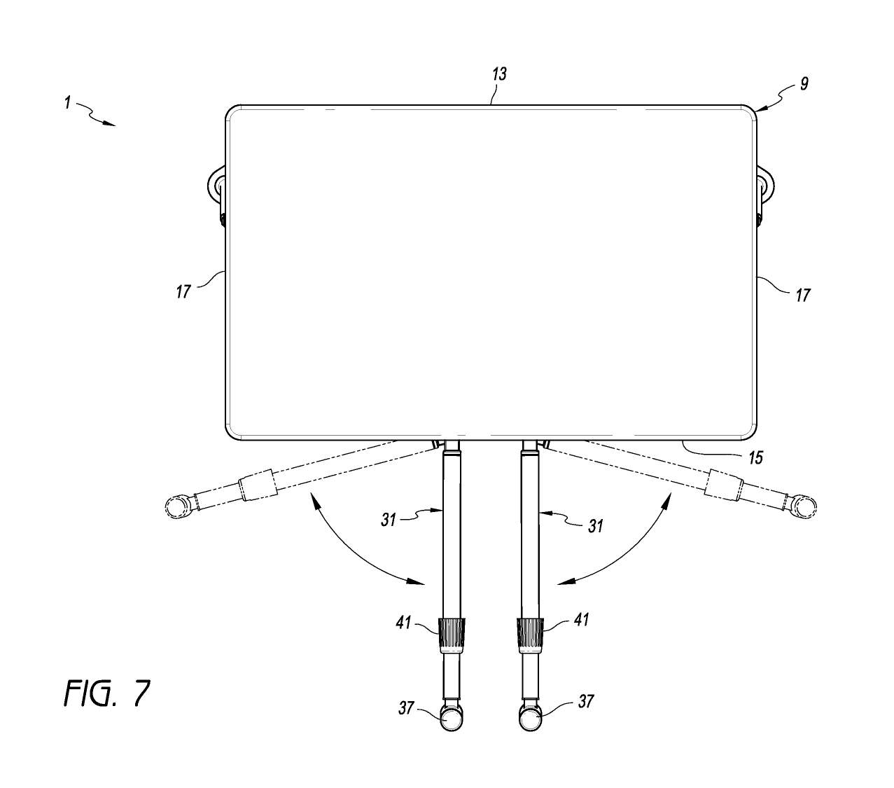

FIGS. 6-7 illustrate two views of the portable support device in which the spacer bars have variable components. Each of the spacer bars 31 can include an adjustable length mechanism 41. As illustrated in FIG. 6, the adjustable length mechanism 41 can be engaged to extend or contract the spacer bar 31. In some embodiments, the adjustable length mechanism 41 can include one or more telescoping segments that function to extend or contract the spacer bar 31, and a tightening sheath that can be screwed or unscrewed to loosen and to lock the adjustable length mechanism 41.

As noted above, first end 33 of the each spacer bar 31 can be attached to the support base 9 by a hinge joint 38 similar to that used to connect struts 7 to the opposing edges 17 of the support base 9. In some embodiments, the hinge joint 38 can permit the spacer bars 31 to rotate substantially within the plane of the support base 9. For example, each spacer bar 31 can be rotated to be substantially parallel to trailing edge 15, or can be rotated to form an oblique angle with trailing edge 15. In addition, in some embodiments each spacer bar 31 can be positioned at any angular orientation therebetween.

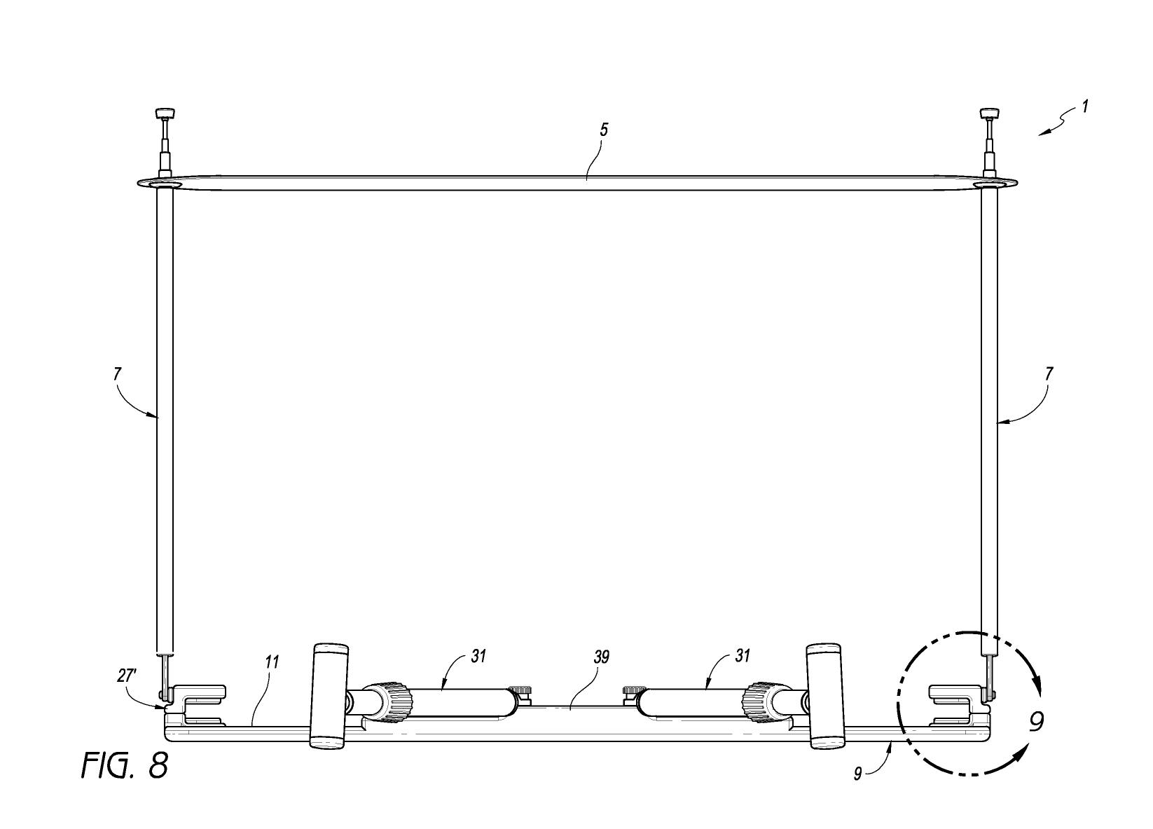

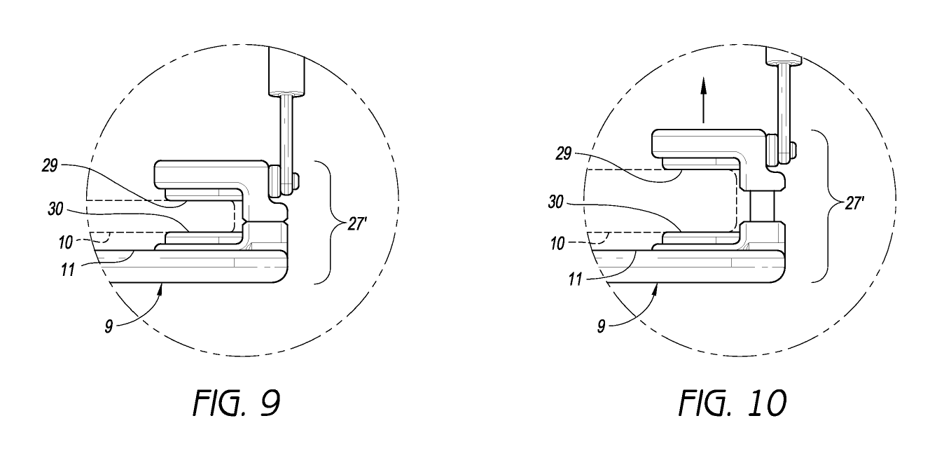

FIG. 8 shows a rear elevation view of a portable support device with adjustable or expandable clamps 27′, according to one embodiment, and FIGS. 9-10 showing detailed views of the expandable clamps 27′ shown in FIG. 8. The portable support device 1 is configured largely as described above. However, the expandable clamps 27′ differ from the standard clamps 27 described above. As with the standard clamps 27, the expandable clamps 27′ include a clamping surface 29 that is spaced apart from the top surface 11 of the support base 9. Unlike the standard clamps 27, however, the expandable clamps 27′ include the additional functionality of varying the spacing between the clamping surface 29 and the top surface 11 of the support base 9.

In the illustrated embodiment, the expandable clamps 27′ also include a lower clamping surface 30 that is slightly raised above the top surface 11 of the support base 9. As illustrated, a portable electronic device 10 can be positioned between the clamping surface 29 and the lower clamping surface 30. In other embodiments, the expandable clamp may omit the lower clamping surface, and instead a portable electronic device can be positioned between the clamping surface and the top surface of the support base. As noted above, the portable electronic device 10 can take any number of forms. For example, the portable electronic device 10 can be a laptop, tablet computer, smartphone, PDA, portable DVD player, or similar. The expandable clamps 27′ can receive essentially any parallelepiped object. For example, a book, magazine, or clipboard could similarly be retained by use of the expandable clamp 27′. In addition, the expandable clamps 27′ can receive non-parallelepiped objects, provided that at least a portion of the object can be retained between the clamping surface 29 and the top surface 11 of the support base 9.

The expandable clamps 27′ can be configured to be biased towards the contracted position. For example, the expandable clamps 27′ can be spring-loaded, such that in the absence of obstruction, the expandable clamps 27′ assume the contracted position. By biasing the expandable clamps 27′, a more secure fit can be achieved between the clamping surface 29 and an object to be held therein, for example portable electronic device 10.

As illustrated, the expandable clamps 27′ are configured such that the clamping surface 29 remains substantially parallel to the top surface 11 of the support base 9 through the expansion. In other embodiments, the clamping surface 29 may rotate during contraction, such that the clamping surface 29 is no longer parallel to the top surface 11 of the support base 9, similar to a spring-loaded clothespin. In either configuration, the biasing of the clamping surface 29 towards the top surface 11 of the support base 9 can function to secure the portable electronic device 10 in place.

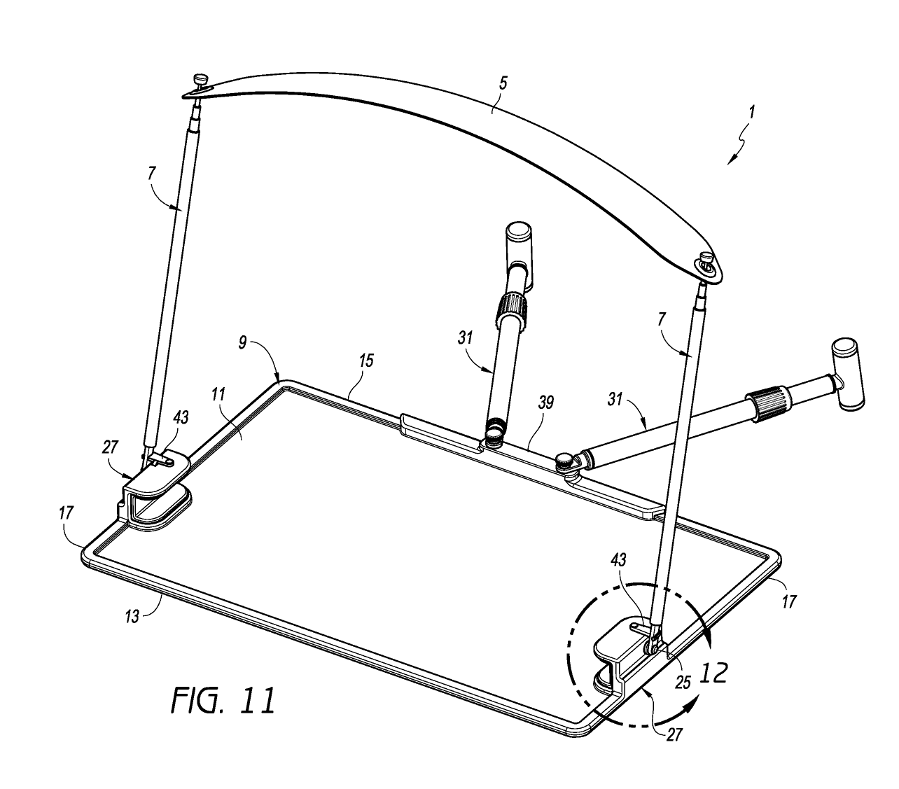

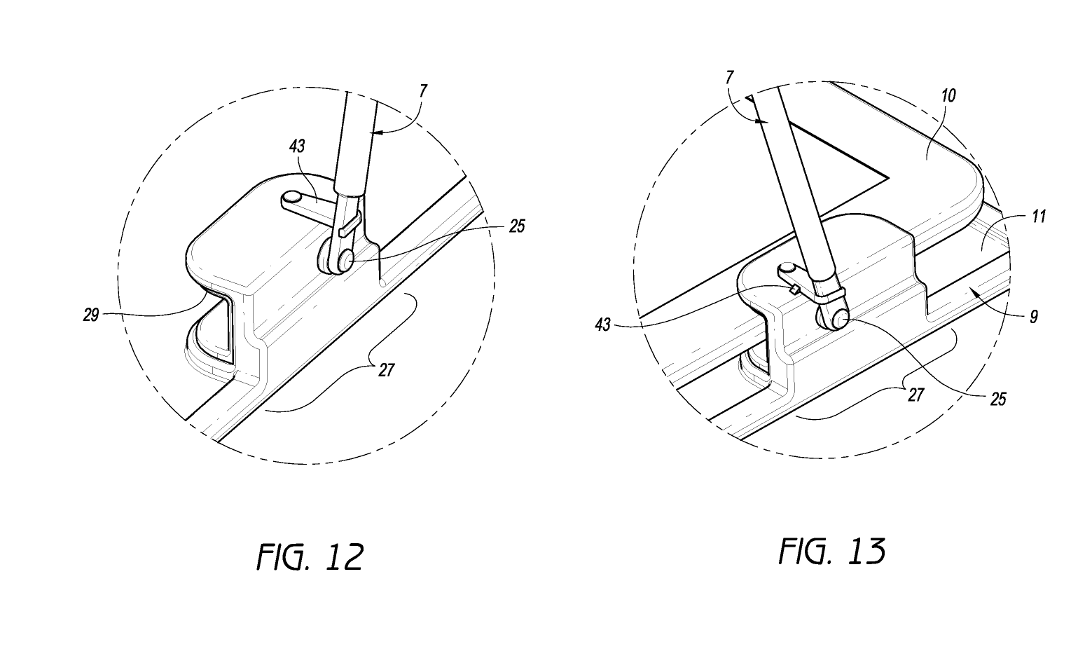

FIG. 11 shows a perspective view of a portable support device with strut locking mechanisms, according to one embodiment, with FIGS. 12-13 showing detailed views of the strut locking mechanisms shown in FIG. 11. As noted above, the struts 7 can be connected to the support base 9 by hinge 25. The hinge 25 can permit free rotation of the struts 7 with respect to the support base 9. In use, however, it can be advantageous to secure the relative orientation of the struts 7 and the support base 9. Without securing the relative positions, a user may find that the support base 9 rotates with respect to the struts 7 depending on how the user interacts with a device placed on the top surface 11 of the support base 9.

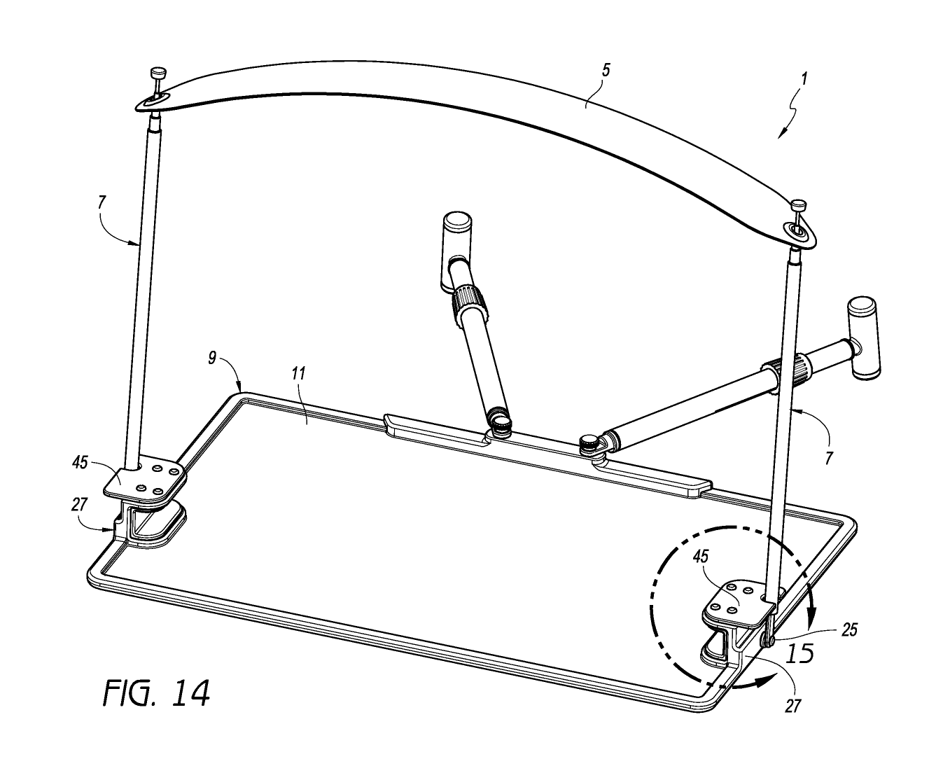

Accordingly, in some embodiments a locking clasp 43 can be attached to the top surface of each clamp 27, opposite the clamping surface 29. As illustrated the clasp 43 can rotate to alternately engage or disengage the strut 7. Once the clasp 43 is engaged with the strut 7, the rotational motion of strut 7 about its hinge 25 is limited. In the illustrated embodiment, the rotational motion of strut 7 is only limited in one direction. In other embodiments, and as discussed in more detail below with respect to FIGS. 14-17, the rotational motion of the strut 7 may be limited in both directions.

As illustrated in FIG. 13, the clasp 43 can engage the strut 7 while a portable electronic device 10 is positioned within the clamp 27. The clasp may be configured such that upon engagement with the strut 7, the support base 9 is oriented with the top surface 11 substantially orthogonal to a line-of-sight of the user (not shown). Other configurations are possible, and the relative orientation of the strut 7 and the support base 9 can vary depending on the design and positioning of the clasp 43. The clasp can be disengaged from the strut 7 by rotation about its hinged connection to the upper surface of the clamp 27. Once disengaged, the strut 7 is free to rotate with respect to the support base 9.

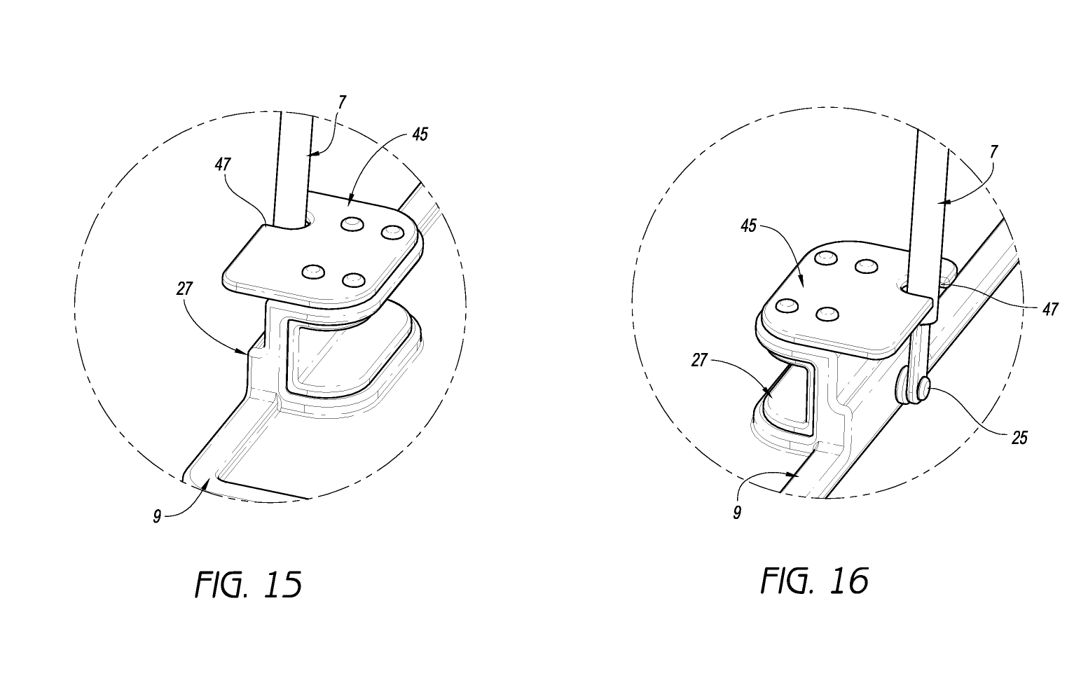

FIG. 14 shows a perspective view of a portable support device with a different strut locking mechanism, particularly clutch plates 45, according to one embodiment, with FIGS. 15-16 showing detailed views of the clutch plates 45 shown in FIG. 14. As noted above, the struts 7 can rotate with respect to the support base 9 by use of the hinge 25. In the illustrated embodiment, however, hinge 25 is positioned lower than in the embodiments illustrated above. As shown, the hinge 25 lies substantially within the plane of the support base 9. To secure the relative orientation of the struts 7 and the support base 9, the clutch plates 45 may be employed in place of the clasps 43 (FIG. 11) described above. A clutch plate 45 is mounted onto the top surface of each clamp 27. Each clutch plate 45 is a generally planar member, and may be made from the same material as support base 9 and/or the clamps 27. Alternatively, the clutch plates 45 may be made from different material. The clutch plates 45 can be bolted onto the top surfaces of the clamps 27. In other embodiments, the clutch plates 45 can be secured to the clamps 27 by an adhesive, such as epoxy, or formed integrally with the clamps 27. Each clutch plate 45 includes a groove 47 disposed on the lateral, outwardly facing surface, desirably in a portion of the clutch plate 45 that extends outwardly beyond the outer dimensions of the support base 9. The groove 47 is dimensioned so as to receive one of the struts 7. In use, the strut 7 can begin in a position separated from the clutch plate 45. As the strut 7 is rotated toward the clutch plate 45, it comes into contact with the clutch plate 45. Due to some flexion in the strut 7, it is able to follow the path of the curved outer surface of clutch plate 45, but once it reaches groove 47, the strut 7 is pressed firmly into place. The strut 7 has a tendency to snap inwardly into the groove due to the location of the hinge 25 inward of the outer side surface of the clutch plate 45, and this tendency is reinforced by increased inward pressure when the flexible strap 5 is around the neck of the user 3 (FIG. 1). Once in position in the groove 47, the rotational movement of the strut 7 is restricted in both directions. As noted above, this may advantageously provide a user with further control over the relative position of the support base 9 and struts 7. In some embodiments, the clutch plates 45 are configured such that upon restricting the rotational movement of the struts 7, the struts 7 intersect the plane of the support base 9 at an angle of between 45 and 135 degrees. In some embodiments, the angle of intersection can be between 80 and 105 degrees. To disengage from the clutch plate 45, the strut 7 is flexed laterally out of the groove, and rotated away from the clutch plate 45.

Although the device 1 may be worn around a user's neck, as illustrated in FIG. 1, alternative uses are possible. For example, with struts 7 engaged with clutch plates 45, the device 1 may be rotated onto its side, such that the plane of support base 9 is nearly perpendicular with a desk or other surface. The struts 7 can rest against the surface of a desk, allowing the entire device 1 to rest in its upright position without requiring user intervention. In this orientation, a user may position a portable electronic device onto the support base 9, which operates as a stand. Rather than viewing the portable electronic device by looking downwards, as described above, the user can view the portable electronic device while seated at a desk or any other position, and need not be in physical contact with the support device 1. As will be understood, various other configurations and uses for the support device 1 are possible.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while several variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for , one another in order to form varying modes of the disclosed invention. Thus, it is intended that the scope of the present invention herein disclosed should not be limited by the particular disclosed embodiments described above, but should be determined only by a fair reading of the claims that follow.

What is claimed is:

1. A portable support device configured to receive a portable electronic device having a bottom surface, the support device comprising:
a generally planar base configured to support the bottom surface of the portable electronic device, the base comprising:
top and bottom opposed surfaces;
opposed leading and trailing edges;
opposed side edges; and
a movement-inhibiting mechanism for retaining the portable electronic device;
a substantially flexible neck strap; and
a pair of substantially rigid struts, each having a first end coupled to the support base and a second end coupled to the neck strap.

2. The portable support device of claim 1, wherein each of the struts are configured to have an adjustable length.

3. The portable support device of claim 2, wherein each of the struts includes a telescoping mechanism for adjusting length.

4. The portable support device of claim 1, further comprising a pair of spacing bars extending from the trailing edge of the support base, wherein the spacing bars extend substantially in the plane of the support base and are configured to space the base away from a user's mid-section when the neck strap is positioned around the neck of the user.

5. The portable support device of claim 4, wherein each of the pair of spacing bars is configured to have an adjustable length.

6. The portable support device of claim 4, wherein each of the pair of spacing bars are configured to be rotated substantially within a plane parallel to the support base, such that the spacing bars can be positioned over a range between a first position substantially parallel to the trailing edge, and a second position forming an oblique angle with the trailing edge.

7. The portable support device of claim 1, wherein the movement-inhibiting mechanism includes a pair of clamps attached to the support base, each of the pair of clamps positioned near one of the side edges of the support base.

8. The portable support device of claim 7, wherein each of the pair of clamps includes a clamping surface spaced apart from the top surface of the support base.

9. The portable support device of claim 8, wherein the pair of clamps are configured to receive a substantially parallelepiped object between the clamping surfaces and the top surface of the support base.

10. The portable support device of claim 9, wherein the clamping surfaces are configured to move relative to the top surface of the support base.

11. The portable support device of claim 10, wherein the clamping surfaces are spring-loaded so as to be biased towards the top surface of the support base.

12. The portable support device of claim 1, further comprising an elongate lip extending from the top surface of the support base at a position near the trailing edge, wherein the lip is substantially parallel to the trailing edge.

13. The portable support device of claim 1, wherein the struts are attached to the support base with hinges, wherein the hinges permit the struts to rotate freely within a plane substantially perpendicular to the plane of the support base.

14. The portable support device of claim 13, further comprising a pair of clutch plates, each of the pair of clutch plates configured to engage one of the struts so as to restrict its rotational movement.

15. The portable support device of claim 14, wherein the hinges are formed on the opposed side edges, each of the clutch plates comprises a substantially planar element extending outwardly beyond one of the side edges and having a groove, the groove configured to receive one of the struts so as to restrict its rotational movement.

16. The portable support device of claim 15, wherein the clutch plates are configured such that upon restricting the rotational movement of the struts, the struts intersect the plane of the support base at an angle between 45 and 135 degrees.

17. The portable support device of claim 16, wherein the struts intersect the plane of the support base at an angle between 80 and 105 degrees.

18. A portable support device configured to receive a portable electronic device having a bottom surface, the support device comprising:
a support base configured to receive the portable electronic device;
a neck strap configured to rest against a back side of a user's neck; and
a pair of substantially rigid struts coupled at one end to the support base and at the other end to the neck strap, the struts configured to pass in front of a user's shoulders, such that the support base rests in front of a user's mid-section.
